(19) United States
(12) Patent Application Publication
(10) Pub. No.: US 2025/0340732 A1
(43) Pub. Date: Nov. 6, 2025

(54) MOLDING RESIN COMPOSITION AND ELECTRONIC COMPONENT DEVICE

(71) Applicant: RESONAC CORPORATION, Tokyo (JP)

(72) Inventors: Arisa YAMAUCHI, Minato-ku, Tokyo (JP); Masashi YAMAURA, Minato-ku, Tokyo (JP); Tomoki HIRAI, Minato-ku, Tokyo (JP); Mika TANAKA, Minato-ku, Tokyo (JP); Ayumi NAKAYAMA, Minato-ku, Tokyo (JP); Yuta SUKEGAWA, Minato-ku, Tokyo (JP)

(73) Assignee: RESONAC CORPORATION, Tokyo (JP)

(21) Appl. No.: 18/861,593

(22) PCT Filed: Jun. 9, 2023
(86) PCT No.: PCT/JP2023/021622

§ 371 Date: Oct. 30, 2024

(30) Foreign Application Priority Data
Jun. 10, 2022 (JP) 2022-094676

(51) Int. Cl. C08L 63/04; C08G 59/08; C08G 59/24; C08G 59/62; C08K 3/22; C08K 5/5397

(52) U.S. Cl. CPC C08L 63/04; C08G 59/08; C08G 59/245; C08G 59/621; C08K 5/5397; C08K 2003/2227; C08K 2003/2237; C08K 2201/005; C08L 2203/20

(57) ABSTRACT

A molding resin composition according to the present invention includes a curable resin, an inorganic filler, and a stress relaxer. The inorganic filler includes: at least one of silica particles and alumina particles; and calcium titanate particles. The stress relaxer includes at least one of an indene/styrene/coumarone copolymer, a trialkyl phosphine oxide, and a triaryl phosphine oxide.

### TECHNICAL FIELD

The present disclosure relates to a molding resin composition and an electronic component device.

### RELATED ART

In recent years, the demand for more sophisticated, lighter, thinner, and smaller electronic devices has led to higher-density integration of electronic components and even higher-density mounting, and the semiconductor packages used in these electronic devices are becoming smaller and smaller than ever before. Furthermore, the radio waves used for communication among electronic devices are also becoming higher in frequency.

From the viewpoints of miniaturization of semiconductor packages and compatibility with high frequency, high dielectric constant epoxy resin compositions used for sealing semiconductor elements have been proposed (see, for example, Patent Documents 1 to 3).

For example, Patent Documents 4 and 5 disclose a thermosetting resin composition containing an active ester resin as an epoxy resin curing agent, which is said to be capable of keeping the dielectric tangent of the cured product low.

### CITATION LIST

### Patent Documents

Patent Document 1: Japanese Patent Application Laid-Open No. 2015-036410
Patent Document 2: Japanese Patent Application Laid-Open No. 2017-057268
Patent Document 3: Japanese Patent Application Laid-Open No. 2018-141052
Patent Document 4: Japanese Patent Application Laid-Open No. 2012-246367
Patent Document 5: Japanese Patent Application Laid-Open No. 2014-114352

### SUMMARY OF INVENTION

### Technical Problem

A molding resin composition including an epoxy resin, a curing agent, and an inorganic filler is, for example, a material for sealing electronic components such as semiconductor elements. If a material with a high dielectric tangent is used as the molding resin composition, the transmitted signal is converted into heat due to transmission loss, and the communication efficiency is likely to decrease. Here, the amount of transmission loss that occurs when radio waves transmitted for communication are converted into heat in a dielectric is expressed as the product of the frequency, the square root of the relative dielectric constant, and the dielectric tangent. The transmitted signal is easily converted into heat in proportion to the frequency. Particularly, the radio waves used for communication have become higher in frequency in recent years in order to cope with an increase in the number of channels that accompanies the diversification of information, and therefore there is a demand for a molding resin composition that can mold a cured product having a low relative dielectric constant and a low dielectric tangent. On the other hand, the larger the relative dielectric constant, the more possible it is to miniaturize the substrate and the semiconductor package. Therefore, from the viewpoints of suppressing transmission loss and miniaturizing the substrate or the like, it is desirable to ensure a low dielectric tangent while suppressing excessive increase and decrease in relative dielectric constant to maintain the relative dielectric constant.

The present disclosure provides a molding resin composition that can mold a cured product having a low dielectric tangent while maintaining a relative dielectric constant, and an electronic component device using the same.

### Solution to Problem

Specific means for solving the problem include the following aspects.
<1> A molding resin composition includes:
   a curable resin;
   an inorganic filler including at least one of silica particles and alumina particles, and calcium titanate particles; and
   a stress relaxer,
   in which the stress relaxer includes at least one of an indene-styrene-coumarone copolymer, a trialkylphosphine oxide, and a triarylphosphine oxide.
<2> In the molding resin composition according to <1>, a content of the calcium titanate particles is 30% by volume to 90% by volume based on the entire inorganic filler.
<3> In the molding resin composition according to <1> or <2>, the curable resin includes an epoxy resin, and the molding resin composition further includes a curing agent.
<4> In the molding resin composition according to <3>, the curing agent includes an active ester compound.
<5> In the molding resin composition according to <3> or <4>, the curing agent includes a phenol curing agent.
<6> In the molding resin composition according to <5>, the phenol curing agent includes a melamine-modified phenol resin.
<7> In the molding resin composition according to any one of <1> to <6>, a total content of the inorganic filler is more than 55% by volume based on the entire molding resin composition.
<8> The molding resin composition according to any one of <1> to <7> is used for a high-frequency device.
<9> The molding resin composition according to any one of <1> to <8> is used for sealing an electronic component in a high-frequency device.
<10> The molding resin composition according to any one of <1> to <9> is used for an antenna-in-package.
<11> An electronic component device includes:
   a support member;
   an electronic component disposed on the support member; and
   a cured product of the molding resin composition according to any one of <1> to <10> which seals the electronic component.
<12> In the electronic component device according to <11>, the electronic component includes an antenna.

### Effects of Invention

According to the present disclosure, a molding resin composition that can mold a cured product having a low dielectric tangent while maintaining a relative dielectric constant, and an electronic component device using the same are provided.

### DESCRIPTION OF EMBODIMENTS

In the present disclosure, the term “step” includes not only a step that is independent of other steps, but also a step that cannot be clearly distinguished from other steps as long as the purpose of the step is achieved.

In the present disclosure, the numerical range indicated using “to” includes the numerical values before and after “to” as the minimum value and the maximum value, respectively.

In the present disclosure in which numerical ranges are described in stages, the upper or lower limit described in one numerical range may be replaced with the upper or lower limit of another numerical range described in stages. In addition, in the numerical range described in the present disclosure, the upper or lower limit of the numerical range may be replaced with a value shown in the examples.

In the present disclosure, each component may include multiple types of corresponding substances. In the case where a composition includes multiple types of substances corresponding to each component, the content or amount of each component means the total content or amount of the multiple types of substances present in the composition, unless otherwise specified.

In the present disclosure, each component may include multiple types of corresponding particles. In the case where a composition includes multiple types of particles corresponding to each component, the particle size of each component means the value with respect to a mixture of the multiple types of particles present in the composition, unless otherwise specified.

In the present disclosure, the “total content of silica particles and alumina particles” may be read as the “content of silica particles” or the “content of alumina particles.”

In the present disclosure, the “total of silica particles and alumina particles” may be read as “silica particles” or “alumina particles.”

Embodiments of the present disclosure will be described in detail hereinafter. However, the present disclosure is not limited to the following embodiments. In the following embodiments, the constituent elements (including element steps, etc.) are not essential, unless otherwise specified. The same applies to numerical values and ranges thereof, which do not limit the present disclosure.

### <Molding Resin Composition>

The molding resin composition of the present disclosure includes a curable resin; an inorganic filler including at least one of silica particles and alumina particles, and calcium titanate particles; and a stress relaxer, and the stress relaxer includes at least one of an indene-styrene-coumarone copolymer, a trialkylphosphine oxide, and a triarylphosphine oxide.

As described above, molding resin compositions are required to have low transmission loss in the cured products after molding. From the viewpoint of suppressing transmission loss, it is desirable to achieve a low dielectric tangent. The molding resin composition of the present disclosure uses calcium titanate particles and the above-mentioned stress relaxer, which makes it possible to reduce the dielectric tangent of the cured product.

Furthermore, the molding resin composition of the present disclosure uses calcium titanate particles, which makes it possible to mold a cured product having a low dielectric tangent compared to a case of using barium titanate or the like.

The molding resin composition of the present disclosure uses at least one of silica particles and alumina particles together with calcium titanate particles, which makes it possible to ensure a low dielectric tangent while maintaining the relative dielectric constant.

Hereinafter, each component constituting the molding resin composition will be described. The molding resin composition of the present disclosure includes a curable resin, an inorganic filler, and a stress relaxer, and may contain other components as necessary.

### (Curable Resin)

The molding resin composition of the present disclosure includes a curable resin. The curable resin may be either a thermosetting resin or a photocurable resin, and from the viewpoint of mass productivity, a thermosetting resin is preferable.

Examples of the thermosetting resin include an epoxy resin, a phenol resin, a melamine resin, a urea resin, an unsaturated polyester resin, an alkyd resin, a urethane resin, a polyimide resin such as a bismaleimide resin, a polyamide resin, a polyamideimide resin, a silicone resin, an acrylic resin, etc. From the viewpoints of moldability and electrical characteristics, the thermosetting resin is preferably an epoxy resin.

The molding resin composition may include only one type of curable resin, or may include two or more types of curable resins.

### [Epoxy Resin]

The type of the epoxy resin is not particularly limited as long as the epoxy resin has an epoxy group in the molecule.

The molding resin composition may include only one type of epoxy resin, or may include two or more types of epoxy resins.

Specific examples of the epoxy resin include a novolac type epoxy resin (a phenol novolac type epoxy resin, an o-cresol novolac type epoxy resin, etc.) which is obtained by epoxidizing a novolac resin obtained by condensing or co-condensing at least one phenolic compound selected from the group consisting of phenol compounds such as phenol, cresol, xylenol, resorcin, catechol, bisphenol A, and bisphenol F, and naphthol compounds such as α-naphthol, β-naphthol, and dihydroxynaphthalene, with an aliphatic aldehyde compound such as formaldehyde, acetaldehyde, and propionaldehyde under an acidic catalyst; a triphenylmethane type epoxy resin which is obtained by epoxidizing a triphenylmethane type phenol resin obtained by condensing or co-condensing the phenolic compound with an aromatic aldehyde compound such as benzaldehyde and salicylaldehyde under an acidic catalyst; a copolymer type epoxy resin which is obtained by epoxidizing a novolac resin obtained by co-condensing the phenol compound and naphthol compound with an aldehyde compound under an acidic catalyst; a diphenylmethane type epoxy resin which is a diglycidyl ether of bisphenol A, bisphenol F, etc.; a biphenyl type epoxy resin which is a diglycidyl ether of alkyl-substituted or unsubstituted biphenol; a stilbene type epoxy resin which is a diglycidyl ether of a stilbene-based phenol compound; a sulfur atom-containing epoxy resin which is a diglycidyl ether of bisphenol S, etc.; an epoxy resin which is a glycidyl ether of alcohols such as butanediol, polyethylene glycol, and polypropylene glycol; a glycidyl ester type epoxy resin which is a glycidyl ester of a polycarboxylic acid compound such as phthalic acid, isophthalic acid, and tetrahydrophthalic acid; a glycidylamine type epoxy resin in which active hydrogen bonded to nitrogen atoms of aniline, diaminodiphenylmethane, isocyanuric acid, etc. is substituted with a glycidyl group; a dicyclopentadiene type epoxy resin which is obtained by epoxidizing a co-condensation resin of dicyclopentadiene and a phenol compound; an alicyclic epoxy resin such as vinylcyclohexene diepoxide, 3,4-epoxycyclohexylmethyl-3,4-epoxycyclohexanecarboxylate, and 2-(3,4-epoxy)cyclohexyl-5,5-spiro(3,4-epoxy)cyclohexane-m-dioxane, which is obtained by epoxidizing an olefin bond in the molecule; a paraxylylene-modified epoxy resin which is a glycidyl ether of a paraxylylene-modified phenol resin; a metaxylylene-modified epoxy resin which is a glycidyl ether of a metaxylylene-modified phenol resin; a terpene-modified epoxy resin which is a glycidyl ether of a terpene-modified phenol resin; a dicyclopentadiene-modified epoxy resin which is a glycidyl ether of a dicyclopentadiene-modified phenol resin; a cyclopentadiene-modified epoxy resin which is a glycidyl ether of a cyclopentadiene-modified phenol resin; a polycyclic aromatic ring-modified epoxy resin which is a glycidyl ether of a polycyclic aromatic ring-modified phenol resin; a naphthalene type epoxy resin which is a glycidyl ether of a naphthalene ring-containing phenol resin; a halogenated phenol novolac type epoxy resin; a hydroquinone type epoxy resin; a trimethylolpropane type epoxy resin; a linear aliphatic epoxy resin which is obtained by oxidizing an olefin bond with a peracid such as peracetic acid; an aralkyl type epoxy resin which is obtained by epoxidizing an aralkyl type phenol resin such as a phenol aralkyl resin and a naphthol aralkyl resin; etc. Further examples of the epoxy resin include an epoxidized acrylic resin. These epoxy resins may be used alone or in combination of two or more.

The epoxy resin preferably includes at least one of a biphenyl aralkyl type epoxy resin, a biphenyl type epoxy resin, and an o-cresol novolac type epoxy resin, and more preferably includes a biphenyl aralkyl type epoxy resin and a biphenyl type epoxy resin, or a biphenyl type epoxy resin and an o-cresol novolac type epoxy resin.

The epoxy equivalent (molecular weight/number of epoxy groups) of the epoxy resin is not particularly limited. From the viewpoint of achieving a balance among various characteristics such as moldability, reflow resistance, and electrical reliability, the epoxy equivalent of the epoxy resin is preferably 100 g/eq to 1000 g/eq, and more preferably 150 g/eq to 500 g/eq.

The epoxy equivalent of the epoxy resin is a value measured by a method in accordance with JIS K 7236:2009.

In the case where the epoxy resin is a solid, the softening point or melting point of the epoxy resin is not particularly limited.

The softening point or melting point of the epoxy resin is preferably 40° C. to 180° C. from the viewpoints of moldability and reflow resistance, and more preferably 50° C. to 130° C. from the viewpoints of handleability during preparation of the molding resin composition.

The melting point or softening point of the epoxy resin is a value measured by differential scanning calorimetry (DSC) or a method in accordance with JIS K 7234:1986 (ring and ball method).

The mass proportion of the epoxy resin in the entire molding resin composition is preferably 0.5% by mass to 30% by mass, more preferably 2% by mass to 20% by mass, and even more preferably 3.5% by mass to 13% by mass, from the viewpoints of strength, fluidity, heat resistance, moldability, etc.

### (Curing Agent)

In the case where the curable resin includes an epoxy resin, it is preferable that the molding resin composition of the present disclosure further includes a curing agent.

The type of the curing agent is not particularly limited, and examples thereof include a phenol-based curing agent, an amine-based curing agent, an acid anhydride-based curing agent, a polymercaptan-based curing agent, a polyaminoamide-based curing agent, an isocyanate-based curing agent, a blocked isocyanate-based curing agent, and an active ester compound. The curing agent may be used alone or in combination of two or more. The curing agent may be a solid or a liquid at room temperature and normal pressure (for example, 25° C. and atmospheric pressure).

The curing agent preferably includes an active ester compound from the viewpoint of keeping the dielectric tangent of the cured product low, and the curing agent preferably includes a phenol curing agent from the viewpoints of chemical resistance of the cured product to an alkaline solution and bending strength of the cured product.

The curing agent may include only one type of active ester compound, or may include two or more types of active ester compounds.

The curing agent may include only one type of phenol curing agent, or may include two or more types of phenol curing agents.

The curing agent may include an active ester compound and a phenol curing agent.

### Active Ester Compound

Here, the active ester compound refers to a compound that has one or more ester groups in one molecule that react with an epoxy group, and has epoxy resin curing action.

When an active ester compound is used as the curing agent, the dielectric tangent of the cured product can be kept low compared to a case where a phenol curing agent is used alone as the curing agent. The reason for this is presumed to be as follows.

A secondary hydroxyl group is generated in the reaction between the epoxy resin and the phenol curing agent. In contrast, an ester group is generated in place of a secondary hydroxyl group in the reaction between the epoxy resin and the active ester compound. Since an ester group has a lower polarity than a secondary hydroxyl group, a molding resin composition including an active ester compound as the curing agent can keep the dielectric tangent of the cured product lower than a molding resin composition including only a curing agent that generates a secondary hydroxyl group as the curing agent.

In addition, the polar groups in the cured product increase the water absorption of the cured product, and using an active ester compound as the curing agent can suppress the polar group concentration of the cured product, and suppress the water absorption of the cured product. Then, as the water absorption of the cured product, that is, the content of H₂O which is a polar molecule, is suppressed, the dielectric tangent of the cured product can be kept even lower.

The type of the active ester compound is not particularly limited as long as the active ester compound is a compound having one or more ester groups in the molecule that react with an epoxy group. Examples of the active ester compound include a phenol ester compound, a thiophenol ester compound, an N-hydroxyamine ester compound, an ester of a heterocyclic hydroxy compound, etc.

Examples of the active ester compound include an ester compound obtained from at least one of an aliphatic carboxylic acid and an aromatic carboxylic acid and at least one of an aliphatic hydroxy compound and an aromatic hydroxy compound. An ester compound that uses an aliphatic compound as a polycondensation component tends to have excellent compatibility with the epoxy resin due to the presence of an aliphatic chain. An ester compound that uses an aromatic compound as a polycondensation component tends to have excellent heat resistance due to the presence of an aromatic ring.

Specific examples of the active ester compound include an aromatic ester obtained by the condensation reaction of an aromatic carboxylic acid with a phenolic hydroxyl group. Among these, an aromatic ester obtained by the condensation reaction between an aromatic carboxylic acid and a phenolic hydroxyl group is preferable, which uses as the raw material a mixture of an aromatic carboxylic acid component in which 2 to 4 hydrogen atoms on an aromatic ring, such as benzene, naphthalene, biphenyl, diphenylpropane, diphenylmethane, diphenyl ether, and diphenylsulfonic acid, have been substituted with a carboxy group, a monohydric phenol in which one hydrogen atom on the aromatic ring has been substituted with a hydroxyl group, and a polyhydric phenol in which 2 to 4 hydrogen atoms on the aromatic ring have been substituted with a hydroxyl group. That is, it is preferable to use an aromatic ester having a structural unit derived from the aromatic carboxylic acid component, a structural unit derived from the monohydric phenol, and a structural unit derived from the polyhydric phenol.

As a specific example of the active ester compound, Japanese Patent Application Laid-Open No. 2012-246367 describes an active ester resin that has a structure obtained by reacting a phenol resin having a molecular structure in which a phenol compound is bonded via an aliphatic cyclic hydrocarbon group with an aromatic dicarboxylic acid or a halide thereof, and an aromatic monohydroxy compound. The active ester resin is preferably a compound represented by the following structural formula (1).

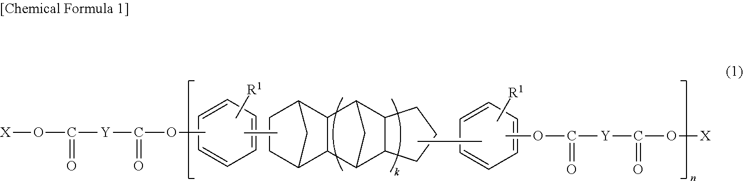

In structural formula (1), R¹ is a hydrogen atom, an alkyl group having 1 to 4 carbon atoms, or a phenyl group; X is an unsubstituted benzene ring, an unsubstituted naphthalene ring, a benzene ring or a naphthalene ring substituted with an alkyl group having 1 to 4 carbon atoms, or a biphenyl group; Y is a benzene ring, a naphthalene ring, or a benzene ring or a naphthalene ring substituted with an alkyl group having 1 to 4 carbon atoms; k is 0 or 1; and n represents the average number of repetitions and is 0 to 5.

Specific examples of the compound represented by structural formula (1) include the following exemplary compounds (1-1) to (1-10). t-Bu in the structural formula is a tert-butyl group.

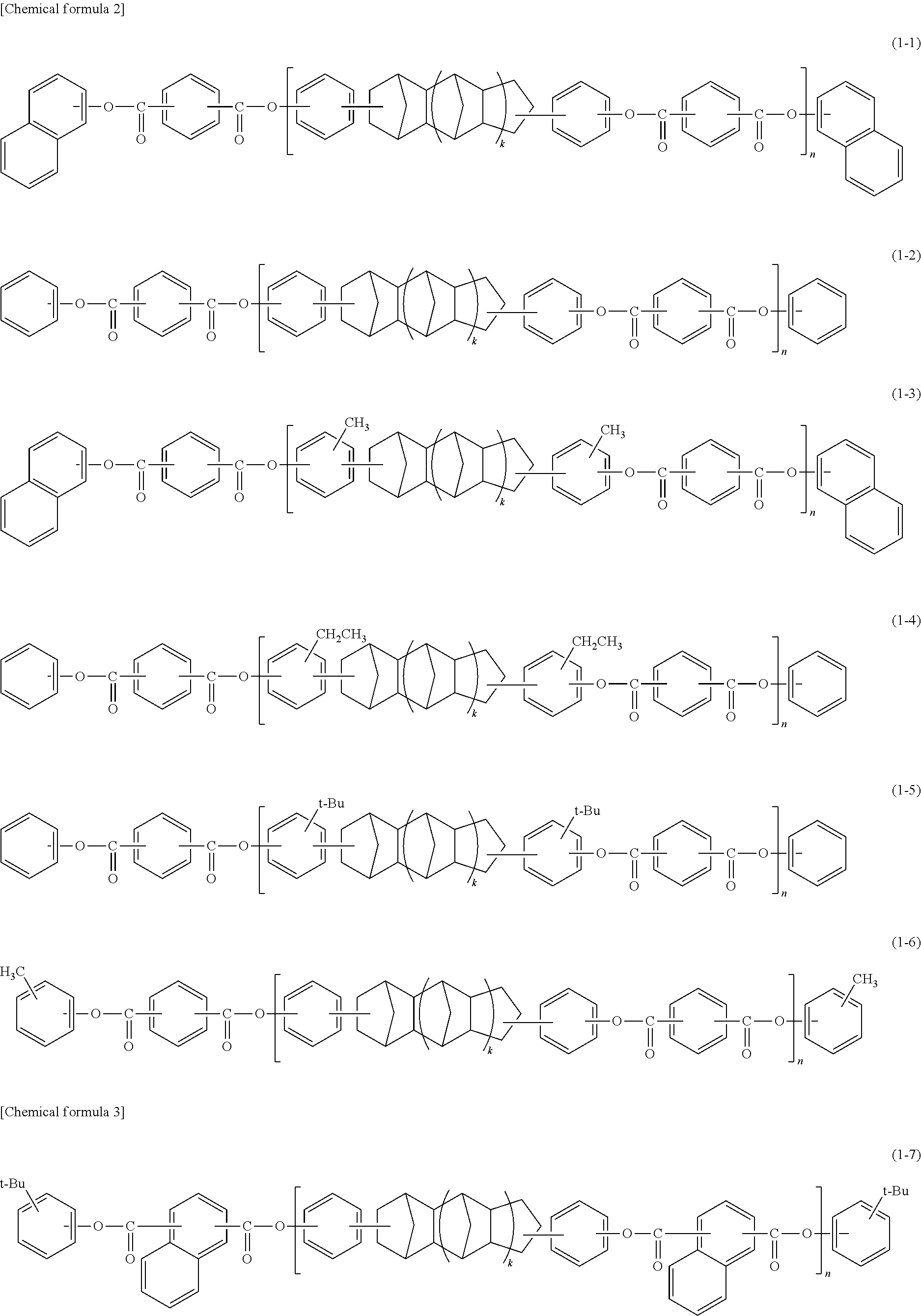

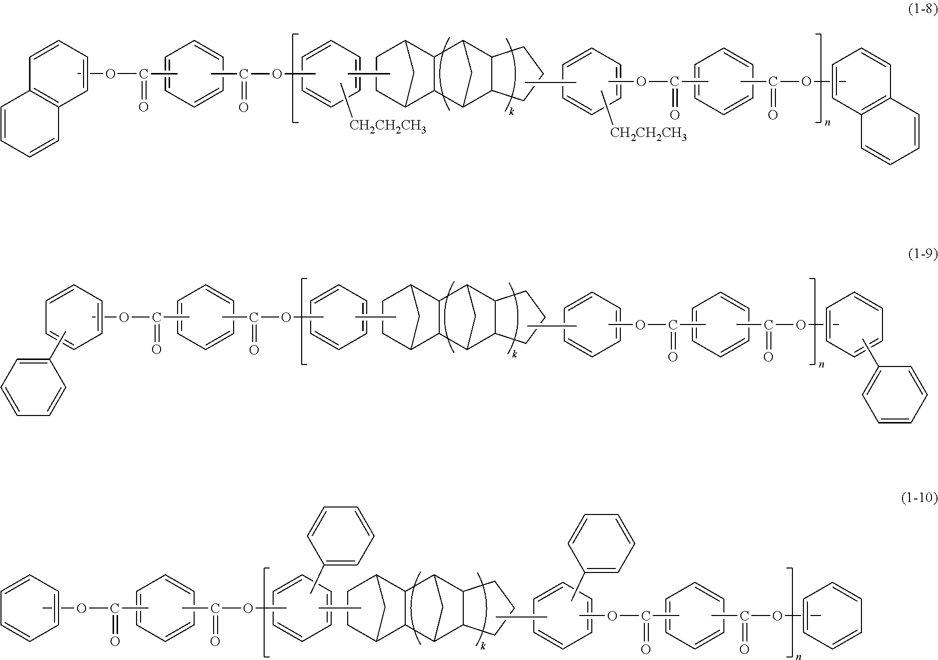

As another specific example of the active ester compound, Japanese Patent Application Laid-Open No. 2014-114352 describes a compound represented by the following structural formula (2) and a compound represented by the following structural formula (3).

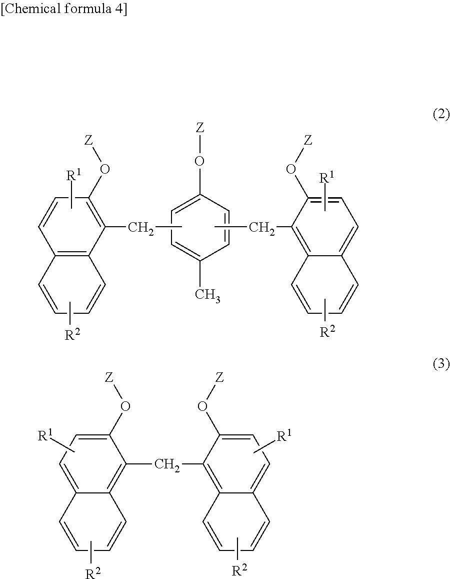

In structural formula (2), R¹ and R² each independently represent a hydrogen atom, an alkyl group having 1 to 4 carbon atoms, or an alkoxy group having 1 to 4 carbon atoms; Z represents an ester-forming structural moiety (z1) selected from the group consisting of an unsubstituted benzoyl group, an unsubstituted naphthoyl group, a benzoyl group or a naphthoyl group substituted with an alkyl group having 1 to 4 carbon atoms, and an acyl group having 2 to 6 carbon atoms, or a hydrogen atom (z2); and at least one of Z is an ester-forming structural moiety (z1).

In structural formula (3), R¹ and R² each independently represent a hydrogen atom, an alkyl group having 1 to 4 carbon atoms, or an alkoxy group having 1 to 4 carbon atoms; Z represents an ester-forming structural moiety (z1) selected from the group consisting of an unsubstituted benzoyl group, an unsubstituted naphthoyl group, a benzoyl group or a naphthoyl group substituted with an alkyl group having 1 to 4 carbon atoms, and an acyl group having 2 to 6 carbon atoms, or a hydrogen atom (z2); and at least one of Z is an ester-forming structural moiety (z1).

Specific examples of the compound represented by structural formula (2) include the following exemplary compounds (2-1) to (2-6).

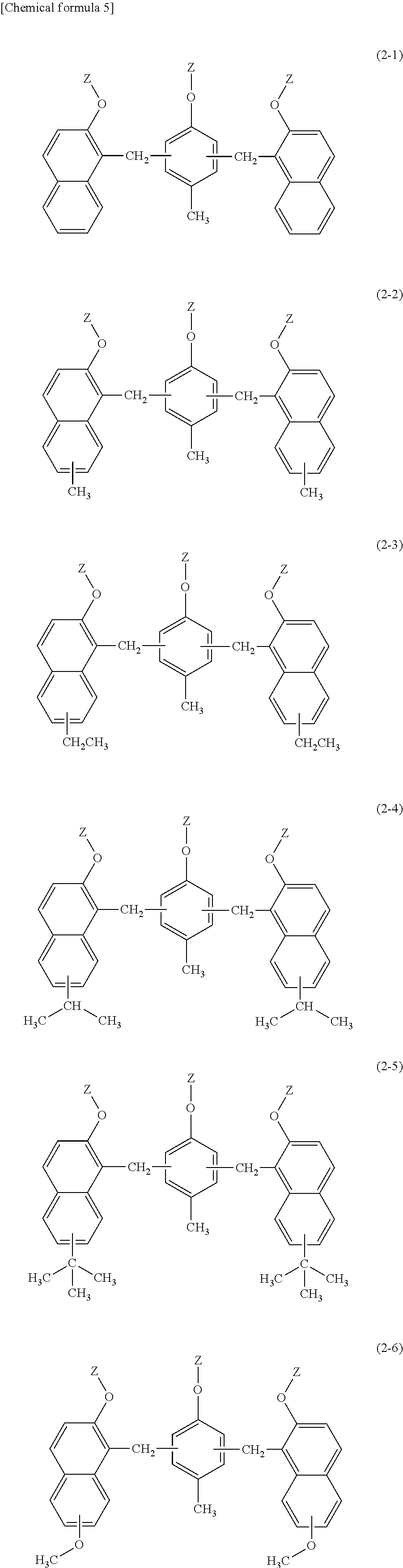

Specific examples of the compound represented by structural formula (3) include the following exemplary compounds (3-1) to (3-6).

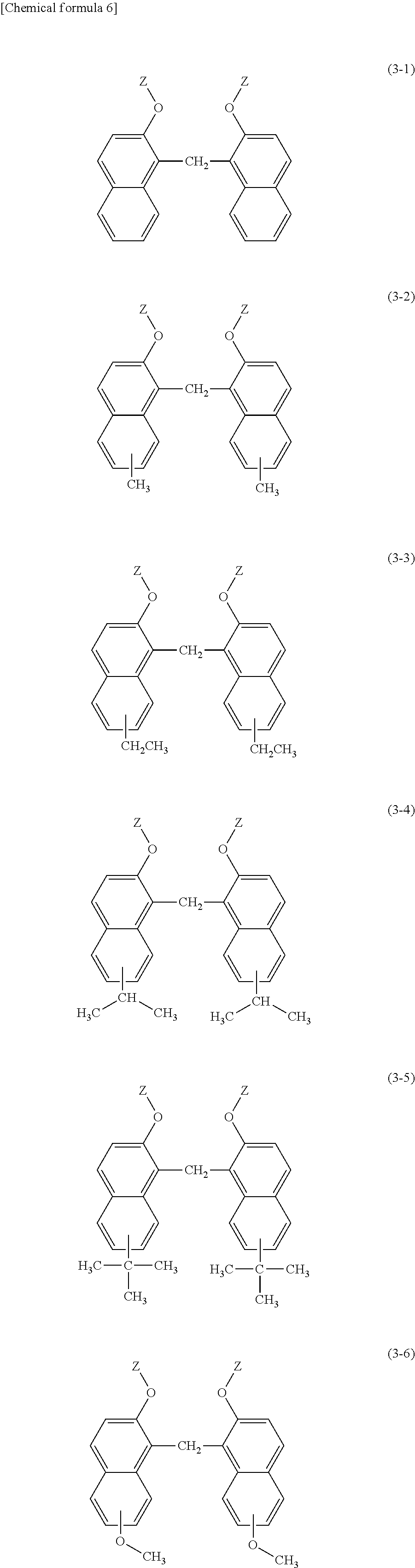

A commercially available product may be used as the active ester compound. Examples of the commercially available active ester compound include active ester compounds including a dicyclopentadiene type diphenol structure such as “EXB9451,” “EXB9460,” “EXB 9460S,” and “HPC-8000-65T” (manufactured by DIC Corporation); active ester compounds including an aromatic structure such as “EXB9416-70BK,” “EXB-8,” and “EXB-9425” (manufactured by DIC Corporation); active ester compounds including an acetylated phenol novolac such as “DC808” (manufactured by Mitsubishi Chemical Corporation); active ester compounds including a benzoylated phenol novolac such as “YLH1026” (manufactured by Mitsubishi Chemical Corporation); etc.

The ester equivalent (molecular weight/number of ester groups) of the active ester compound is not particularly limited. From the viewpoint of achieving a balance among various characteristics such as moldability, reflow resistance, and electrical reliability, the ester equivalent is preferably 150 g/eq to 400 g/eq, more preferably 170 g/eq to 300 g/eq, and even more preferably 200 g/eq to 250 g/eq.

The ester equivalent of the active ester compound is a value measured by a method in accordance with JIS K 0070:1992.

### Phenol Curing Agent

Specific examples of the phenol curing agent include a polyhydric phenol compound such as resorcin, catechol, bisphenol A, bisphenol F, and substituted or unsubstituted biphenol; a novolac type phenol resin which is obtained by condensing or co-condensing at least one phenolic compound selected from the group consisting of phenol compounds such as phenol, cresol, xylenol, resorcin, catechol, bisphenol A, bisphenol F, phenylphenol, and aminophenol, and naphthol compounds such as α-naphthol, β-naphthol, and dihydroxynaphthalene, with an aldehyde compound such as formaldehyde, acetaldehyde, and propionaldehyde under an acidic catalyst; an aralkyl type phenol resin such as a phenol aralkyl resin and a naphthol aralkyl resin synthesized from the phenolic compound and dimethoxy-para-xylene, bis(methoxymethyl)biphenyl, etc.; a paraxylylene-modified phenol resin, a metaxylylene-modified phenol resin; a melamine-modified phenol resin; a terpene-modified phenol resin; a dicyclopentadiene type phenol resin and a dicyclopentadiene type naphthol resin synthesized by copolymerization of the phenolic compound with dicyclopentadiene; a cyclopentadiene-modified phenol resin; a polycyclic aromatic ring-modified phenol resin; a biphenyl type phenol resin; a triphenylmethane type phenol resin which is obtained by condensing or co-condensing the phenolic compound with an aromatic aldehyde compound such as benzaldehyde and salicylaldehyde under an acidic catalyst; and a phenol resin which is obtained by copolymerizing two or more of these. These phenol curing agents may be used alone or in combination of two or more.

Among these, the phenol curing agent preferably includes an aralkyl type phenol resin and a melamine-modified phenol resin, and more preferably includes a melamine-modified phenol resin from the viewpoint of improving the adhesion (particularly adhesion at high temperature) of a cured product of the molding resin composition to adherends such as an electronic component and a support member on which the electronic component is mounted.

The reactive group equivalent (for example, hydroxyl group equivalent) of the phenol curing agent is not particularly limited. From the viewpoint of achieving a balance among various characteristics such as moldability, reflow resistance, and electrical reliability, the reactive group equivalent of the phenol curing agent is preferably 70 g/eq to 1000 g/eq, and more preferably 80 g/eq to 500 g/eq.

The hydroxyl group equivalent of the phenol curing agent is a value measured by a method in accordance with JIS K 0070:1992.

The softening point or melting point of the curing agent is not particularly limited. The softening point or melting point of the curing agent is preferably 40° C. to 180° C. from the viewpoints of moldability and reflow resistance, and more preferably 50° C. to 130° C. from the viewpoint of handleability during production of the molding resin composition.

The melting point or softening point of the curing agent is a value measured in the same manner as the melting point or softening point of the epoxy resin.

The equivalent ratio of the epoxy resin to the curing agent (preferably the total of the active ester compound and the phenol curing agent), that is, the ratio of the number of functional groups in the curing agent to the number of functional groups in the epoxy resin (number of functional groups in the curing agent/number of functional groups in the epoxy resin), is not particularly limited. From the viewpoint of keeping the amount of each unreacted component small, the equivalent ratio is preferably set in the range of 0.5 to 2.0, and more preferably in the range of 0.6 to 1.3. From the viewpoints of moldability and reflow resistance, the equivalent ratio is more preferably set in the range of 0.8 to 1.2.

In the case where the curing agent includes an active ester compound and a phenol curing agent, the molar ratio of the ester group included in the active ester compound to the reactive group included in the phenol curing agent (ester group/reactive group in the phenol curing agent) is preferably 9/1 to 1/9, more preferably 8/2 to 2/8, and even more preferably 3/7 to 7/3.

The mass proportion of the active ester compound in the total amount of the active ester compound and the phenol curing agent is preferably 40% by mass to 90% by mass, more preferably 50% by mass to 80% by mass, and even more preferably 55% by mass to 70% by mass, from the viewpoint of excellent bending strength after curing of the molding resin composition and the viewpoint of keeping the dielectric tangent of the cured product low.

The mass proportion of the phenol curing agent in the total amount of the active ester compound and the phenol curing agent is preferably 10% by mass to 60% by mass, more preferably 20% by mass to 50% by mass, and even more preferably 30% by mass to 45% by mass, from the viewpoint of excellent bending strength after curing of the molding resin composition and the viewpoint of keeping the dielectric tangent of the cured product low.

In the case where the phenol curing agent includes a melamine-modified phenol resin, the content of the melamine-modified phenol resin is preferably 1% by mass to 20% by mass, more preferably 2% by mass to 15% by mass, and even more preferably 3% by mass to 10% by mass, based on the total amount of the epoxy resin. When the content of the melamine-modified phenol resin is 1% by mass or more based on the total amount of the epoxy resin, the cured product of the molding resin composition tends to have improved adhesion (particularly adhesion at high temperature) to adherends such as an electronic component and a support member on which the electronic component is mounted. When the content of the melamine-modified phenol resin is 20% by mass or less based on the total amount of the epoxy resin, the cured product tends to have excellent bending strength.

In the case where the molding resin composition includes an epoxy resin and a curing agent, the content of the curable resin other than the epoxy resin may be less than 5% by mass, 4% by mass or less, or 3% by mass or less, based on the entire molding resin composition.

### (Inorganic Filler)

The molding resin composition of the present disclosure includes an inorganic filler including at least one of silica particles and alumina particles, and calcium titanate particles.

The inorganic filler may include other fillers in addition to silica particles, alumina particles, and calcium titanate particles.

### At Least One of Silica Particles and Alumina Particles

The inorganic filler includes at least one of silica particles and alumina particles. The inorganic filler may include only one of silica particles and alumina particles, or may include both.

The silica particles and alumina particles may each independently be used alone or in combination of two or more. The silica particles and alumina particles may be a mixture of two or more types of fillers having different volume average particle sizes.

The silica particles are not particularly limited, and examples thereof include fused silica, crystalline silica, glass, etc. The shape of the silica particles is not particularly limited, and examples thereof include a spherical shape, an elliptical shape, an irregular shape, etc. The silica particles may be crushed.

### the Silica Particles May be Surface-Treated.

The shape of the alumina particles is not particularly limited, and examples thereof include a spherical shape, an elliptical shape, an irregular shape, etc. The alumina particles may be crushed.

### the Alumina Particles May be Surface-Treated.

From the viewpoints of relative dielectric constant and thermal conductivity, the inorganic filler preferably includes alumina particles.

From the viewpoint of low dielectric tangent, the total content of the silica particles and alumina particles is preferably 20% by volume to 60% by volume, more preferably 25% by volume to 55% by volume, and even more preferably 30% by volume to 50% by volume, based on the entire inorganic filler.

The content (% by volume) of silica particles, the content (% by volume) of alumina particles, and the content (% by volume) of calcium titanate particles described below relative to the entire inorganic filler can be determined by the following method.

A thin sample of the cured product of the molding resin composition is photographed with a scanning electron microscope (SEM). An arbitrary area S is specified in the SEM image, and the total area A of the inorganic filler included in the area S is calculated. Next, an SEM-EDX (energy dispersive X-ray spectrometer) is used to identify the elements of the inorganic filler, thereby determining the total area B of specific particles such as silica particles, alumina particles, and calcium titanate particles included in the total area A of the inorganic filler. The total area B of the specific particles is divided by the total area A of the inorganic filler, and the resulting value is converted into a percentage (%). This value is the content (% by volume) of the specific particles relative to the entire inorganic filler.

The area S is set to be sufficiently large compared to the size of the inorganic filler. For example, the area S is set so that 100 or more inorganic fillers are included. The area S may be the total of a plurality of cut surfaces.

In the case where the molding resin composition includes an epoxy resin and a curing agent, the mass ratio of the total of the silica particles and alumina particles to the total of the epoxy resin and the curing agent in the molding resin composition (total of silica particles and alumina particles/total of epoxy resin and curing agent) is preferably 1 to 25, more preferably 2 to 20, even more preferably 3 to 15, and particularly preferably 4 to 12, from the viewpoint of achieving a balance between dielectric tangent and fluidity.

The volume average particle size of the silica particles and the volume average particle size of the alumina particles are not particularly limited. The volume average particle size of the silica particles and the volume average particle size of the alumina particles are each independently preferably 0.2 μm to 100 μm, and more preferably 0.5 μm to 50 μm. When the volume average particle size is 0.2 μm or more, an increase in the viscosity of the molding resin composition tends to be further suppressed. When the volume average particle size is 100 μm or less, the filling property of the molding resin composition tends to be further improved.

The volume average particle size of the silica particles and the volume average particle size of the alumina particles are measured by placing the molding resin composition in a crucible and leaving the molding resin composition at 800° C. for 4 hours to incinerate the molding resin composition. The obtained ash is observed by SEM, separated by shape, and the particle size distribution is obtained from the observed image. From the particle size distribution, the volume average particle size of the silica particles and the volume average particle size of the alumina particles can be determined as the volume average particle size (D50). The volume average particle size of the silica particles and the volume average particle size of the alumina particles may be determined by measurement using a laser diffraction/scattering type particle size distribution measuring device (for example, LA920, manufactured by Horiba, Ltd.).

The volume average particle size of the silica particles and the volume average particle size of the alumina particles may each independently be 3 μm or more, or 5 μm or more, from the viewpoint of the viscosity of the molding resin composition, and may be 10 μm or more, or 20 μm or more, from the viewpoint of the fluidity of the molding resin composition. The volume average particle size of the silica particles and the volume average particle size of the alumina particles may be 50 μm or less, or may be 30 μm or less.

### Calcium Titanate Particles

The inorganic filler includes calcium titanate particles. The shape of the calcium titanate particles is not particularly limited, and examples thereof include a spherical shape, an elliptical shape, an irregular shape, etc. In addition, the calcium titanate particles may be crushed.

### the Calcium Titanate Particles May be Surface-Treated.

The calcium titanate particles may be a mixture of two or more types of fillers having different volume average particle sizes.

In the case where the molding resin composition includes an epoxy resin and a curing agent, the mass ratio of the calcium titanate particles to the total of the epoxy resin and the curing agent in the molding resin composition (calcium titanate particles/total of epoxy resin and curing agent) is preferably 1 to 25, more preferably 2 to 20, even more preferably 3 to 15, and particularly preferably 4 to 12, from the viewpoint of achieving a balance between dielectric tangent and fluidity.

The volume average particle size of the calcium titanate particles is preferably 0.1 μm to 100 μm, more preferably 0.2 μm to 80 μm, even more preferably 0.5 μm to 40 μm, particularly preferably 0.5 μm to 30 μm, and extremely preferably 0.5 μm to 25 μm.

The volume average particle size of the calcium titanate particles can be measured as follows. The molding resin composition is placed in a crucible and left at 800° C. for 4 hours to be incinerated. The obtained ash is observed by SEM, separated by shape, and the particle size distribution is obtained from the observed image. From the particle size distribution, the volume average particle size of the calcium titanate particles can be determined as the volume average particle size (D50). In addition, the volume average particle size of the calcium titanate particles may be determined by measurement using a laser diffraction/scattering type particle size distribution measuring device (for example, LA920, manufactured by Horiba, Ltd.).

From the viewpoint of achieving a balance between relative dielectric constant and dielectric tangent, the content of the calcium titanate particles is preferably 20% by volume to 90% by volume, more preferably 30% by volume to 90% by volume, even more preferably 40% by volume to 85% by volume, and particularly preferably 50% by volume to 80% by volume, based on the entire inorganic filler.

The total content of the silica particles, alumina particles, and calcium titanate particles may be 90% by volume or more, 95% by volume or more, or 100% by volume, based on the entire inorganic filler.

### Other Fillers

The inorganic filler may include other fillers in addition to silica particles, alumina particles, or calcium titanate particles.

The shape of the other fillers is not particularly limited, and examples thereof include a spherical shape, an elliptical shape, an irregular shape, etc. In addition, the other fillers may be crushed.

### the Other Fillers May be Surface-Treated.

The other fillers may be used alone or in combination of two or more. The other fillers may be a mixture of two or more fillers having different volume average particle sizes.

The types of the other fillers are not particularly limited. Specific examples of the material of the other fillers include inorganic materials such as calcium carbonate, zirconium silicate, calcium silicate, silicon nitride, aluminum nitride, boron nitride, beryllia, zirconia, zircon, fosterite, steatite, spinel, mullite, titania, talc, clay, and mica.

An inorganic filler having a flame retardant effect may be used as the other fillers. Examples of the inorganic filler having a flame retardant effect include aluminum hydroxide, magnesium hydroxide, composite metal hydroxide such as composite hydroxide of magnesium and zinc, zinc borate, etc.

The content of the other fillers may be 10% by volume or less, 5% by mass or less, or 0% by volume or less, based on the entire inorganic filler.

The other fillers may include titanium compound particles other than calcium titanate particles. Examples of the titanium compound particles other than calcium titanate particles include strontium titanate particles, barium titanate particles, potassium titanate particles, magnesium titanate particles, lead titanate particles, aluminum titanate particles, lithium titanate, titanium oxide particles, etc.

However, from the viewpoint of keeping the dielectric tangent of the cured product low, the content of the barium titanate particles is preferably less than 1% by volume, more preferably less than 0.5% by volume, and even more preferably less than 0.1% by volume, based on the entire inorganic filler. In other words, it is preferable that the inorganic filler does not include barium titanate particles or includes barium titanate particles at the above content.

Further, the total content of titanium compound particles other than calcium titanate particles may be less than 1% by volume, less than 0.5% by volume, or less than 0.1% by volume, based on the entire inorganic filler. In other words, the inorganic filler may not include titanium compound particles other than calcium titanate particles, or may include titanium compound particles other than calcium titanate particles at the above content.

The preferred range of the volume average particle size of the other fillers is the same as the preferred ranges of the volume average particle size of the silica particles and the volume average particle size of the alumina particles.

### Content and Characteristics of Entire Inorganic Filler

From the viewpoint of controlling the fluidity and strength of the cured product of the molding resin composition, the content of the entire inorganic filler included in the molding resin composition is preferably more than 55% by volume, more preferably more than 55% by volume and not more than 90% by volume, even more preferably 60% by volume to 85% by volume, particularly preferably 65% by volume to 85% by volume, and extremely preferably 70% by volume to 80% by volume, based on the entire molding resin composition.

The content (% by volume) of the inorganic filler in the molding resin composition can be determined by the following method.

A thin sample of the cured product of the molding resin composition is photographed with a scanning electron microscope (SEM). An arbitrary area S is specified in the SEM image, and the total area A of the inorganic filler included in the area S is calculated. The total area A of the inorganic filler is divided by the area S, and the resulting value is converted into a percentage (%). This value is the content (% by volume) of the inorganic filler in the molding resin composition.

The area S is set to be sufficiently large compared to the size of the inorganic filler. For example, the area S is set so that 100 or more inorganic fillers are included. The area S may be the total of a plurality of cut surfaces.

The inorganic filler may have a biased presence ratio in the direction of gravity when the molding resin composition is cured. In this case, when photographed with an SEM, the entire cured product in the direction of gravity is photographed, and the area S that includes the entire cured product in the direction of gravity is specified.

### (Stress Relaxer)

The molding resin composition of the present disclosure includes a stress relaxer. The stress relaxer includes at least one of an indene-styrene-coumarone copolymer, a trialkylphosphine oxide, and a triarylphosphine oxide. This results in a cured product having a low dielectric tangent. The stress relaxer may include at least one of an indene-styrene-coumarone copolymer and a triphenylphosphine oxide, or may include both an indene-styrene-coumarone copolymer and a triphenylphosphine oxide.

The total content of the indene-styrene-coumarone copolymer, trialkylphosphine oxide, and triarylphosphine oxide is, for example, preferably 1 part by mass to 30 parts by mass, and more preferably 2 parts by mass to 20 parts by mass, based on 100 parts by mass of the curable resin (or 100 parts by mass of the epoxy resin and the curing agent in total).

In the case where the stress relaxer includes both an indene-styrene-coumarone copolymer and a triarylphosphine oxide, the mass ratio thereof, that is, indene-styrene-coumarone copolymer:triarylphosphine oxide, may be 1:1 to 5:1, 1:1 to 3:1, or 1.5:1 to 2.5:1.

The molding resin composition of the present disclosure may include a stress relaxer other than an indene-styrene-coumarone copolymer, a trialkylphosphine oxide, and a triarylphosphine oxide (hereinafter also referred to as “other stress relaxers”). Examples of other stress relaxers include a thermoplastic elastomer such as silicone-based, styrene-based, olefin-based, urethane-based, polyester-based, polyether-based, polyamide-based, and polybutadiene-based elastomers; an organic phosphorus compound such as phosphate ester; rubber particles such as NR (natural rubber), NBR (acrylonitrile-butadiene rubber), acrylic rubber, urethane rubber, and silicone powder; rubber particles having a core-shell structure such as methyl methacrylate-styrene-butadiene copolymer (MBS), methyl methacrylate-silicone copolymer, and methyl methacrylate-butyl acrylate copolymer; etc. The other stress relaxers may be used alone or in combination of two or more.

Examples of the silicone-based stress relaxer include those having an epoxy group, those having an amino group, and those modified with polyether. Silicone compounds such as a silicone compound having an epoxy group and a polyether-based silicone compound are more preferable.

The content of the other stress relaxers may be, for example, 2 parts by mass or less, or 1 part by mass or less, based on 100 parts by mass of the curable resin (or 100 parts by mass of the epoxy resin and the curing agent in total). The molding resin composition may not include other stress relaxers. The lower limit of the content of the other stress relaxers is not particularly limited, and may be 0 parts by mass or 0.1 parts by mass.

From the viewpoint of dielectric tangent, the content of the silicone-based stress relaxer is preferably 20% by mass or less, more preferably 10% by mass or less, even more preferably 7% by mass or less, particularly preferably 5% by mass or less, and extremely preferably 0.5% by mass or less, based on the entire molding resin composition. The lower limit of the content of the silicone-based stress relaxer is not particularly limited, and may be 0% by mass or 0.1% by mass.

### (Curing Accelerator)

The molding resin composition of the present disclosure may include a curing accelerator as necessary. The type of the curing accelerator is not particularly limited, and can be selected depending on the type of epoxy resin, the desired characteristics of the molding resin composition, etc.

Examples of the curing accelerator include diazabicycloalkenes such as 1,5-diazabicyclo[4.3.0]nonene-5 (DBN) and 1,8-diazabicyclo[5.4.0]undecene-7 (DBU), cyclic amidine compounds such as 2-methylimidazole, 2-phenylimidazole, 2-phenyl-4-methylimidazole, 2-ethyl-4-methylimidazole, and 2-heptadecylimidazole; derivatives of the cyclic amidine compounds; phenol novolac salts of the cyclic amidine compounds or derivatives thereof; compounds having intramolecular polarization obtained by adding compounds having a π bond, such as quinone compounds such as maleic anhydride, 1,4-benzoquinone, 2,5-toluquinone, 1,4-naphthoquinone, 2,3-dimethylbenzoquinone, 2,6-dimethylbenzoquinone, 2,3-dimethoxy-5-methyl-1,4-benzoquinone, 2,3-dimethoxy-1,4-benzoquinone, and phenyl-1,4-benzoquinone, and diazophenylmethane, to these compounds; cyclic amidinium compounds such as tetraphenylborate salt of DBU, tetraphenylborate salt of DBN, tetraphenylborate salt of 2-ethyl-4-methylimidazole, and tetraphenylborate salt of N-methylmorpholine; tertiary amine compounds such as pyridine, triethylamine, triethylenediamine, benzyldimethylamine, triethanolamine, dimethylaminoethanol, and tris(dimethylaminomethyl)phenol; derivatives of the tertiary amine compounds; ammonium salt compounds such as tetra-n-butylammonium acetate, tetra-n-butylammonium phosphate, tetraethylammonium acetate, tetra-n-hexylammonium benzoate, and tetrapropylammonium hydroxide; organic phosphines such as primary phosphines such as ethylphosphine and phenylphosphine, secondary phosphines such as dimethylphosphine and diphenylphosphine, and tertiary phosphines such as triphenylphosphine, diphenyl(p-tolyl)phosphine, tris(alkylphenyl)phosphine, tris(alkoxyphenyl)phosphine, tris(alkyl-alkoxyphenyl)phosphine, tris(dialkylphenyl)phosphine, tris(trialkylphenyl)phosphine, tris(tetraalkylphenyl)phosphine, tris(dialkoxyphenyl)phosphine, tris(trialkoxyphenyl)phosphine, trialkylphosphines, dialkylarylphosphines, tris(tetraalkoxyphenyl)phosphine, alkyldiarylphosphines, trinaphthylphosphine, and tris(benzyl)phosphine; phosphine compounds such as complexes of the organic phosphines and organic borons; compounds having intramolecular polarization obtained by adding compounds having a π bond, such as quinone compounds such as maleic anhydride, 1,4-benzoquinone, 2,5-toluquinone, 1,4-naphthoquinone, 2,3-dimethylbenzoquinone, 2,6-dimethylbenzoquinone, 2,3-dimethoxy-5-methyl-1,4-benzoquinone, 2,3-dimethoxy-1,4-benzoquinone, phenyl-1,4-benzoquinone, and anthraquinone, and diazophenylmethane, to the organic phosphines or the phosphine compounds; compounds having intramolecular polarization obtained by reacting the organic phosphines or the phosphine compounds with halogenated phenol compounds such as 4-bromophenol, 3-bromophenol, 2-bromophenol, 4-chlorophenol, 3-chlorophenol, 2-chlorophenol, 4-iodophenol, 3-iodophenol, 2-iodophenol, 4-bromo-2-methylphenol, 4-bromo-3-methylphenol, 4-bromo-2,6-dimethylphenol, 4-bromo-3,5-dimethylphenol, 4-bromo-2,6-di-tert-butylphenol, 4-chloro-1-naphthol, 1-bromo-2-naphthol, 6-bromo-2-naphthol, and 4-bromo-4′-hydroxybiphenyl, followed by a dehydrohalogenation step; tetra-substituted phosphonium compounds such as tetraphenylphosphonium, tetraphenylborate salts of tetra-substituted phosphonium such as tetraphenylphosphonium tetra-p-tolylborate, and salts of tetra-substituted phosphonium with phenolic compounds; salts of tetraalkylphosphonium with partial hydrolysates of aromatic carboxylic acid anhydrides; phosphobetaine compounds; adducts of phosphonium compounds and silane compounds; etc.

The curing accelerator may be used alone or in combination of two or more.

Among these, the curing accelerator is preferably an organic phosphine-containing curing accelerator. Examples of the organic phosphine-containing curing accelerator include the organic phosphines, phosphine compounds such as complexes of the organic phosphines and organic borons, and compounds having intramolecular polarization obtained by adding compounds having a π bond to the organic phosphines or the phosphine compounds, etc.

Among these, particularly suitable curing accelerators include, for example, trialkylphosphines, adducts of trialkylphosphines and quinone compounds, triphenylphosphines, adducts of triphenylphosphines and quinone compounds, adducts of tributylphosphines and quinone compounds, adducts of tri-p-tolylphosphines and quinone compounds, etc.

In the case where the molding resin composition includes a curing accelerator, the amount thereof is preferably 0.1 parts by mass to 30 parts by mass, and more preferably 1 part by mass to 15 parts by mass, based on 100 parts by mass of the curable resin (or 100 parts by mass of the epoxy resin and the curing agent in total). When the amount of the curing accelerator is 0.1 parts by mass or more based on 100 parts by mass of the curable resin (or 100 parts by mass of the epoxy resin and the curing agent in total), the molding resin composition tends to cure well in a short period of time. When the amount of the curing accelerator is 30 parts by mass or less based on 100 parts by mass of the curable resin (or 100 parts by mass of the epoxy resin and the curing agent in total), the curing speed is not too fast and a good molded product tends to be obtained.

### [Various Additives]

The molding resin composition of the present disclosure may include, in addition to the above-mentioned components, various additives such as a coupling agent, an ion exchanger, a release agent, a flame retardant, and a colorant, as exemplified below. The molding resin composition of the present disclosure may include various additives well known in the art, as necessary, in addition to the additives exemplified below.

### (Coupling Agent)

The molding resin composition of the present disclosure may include a coupling agent. From the viewpoint of improving the adhesion between the curable resin, the curing agent, etc. and the inorganic filler, the molding resin composition preferably includes a coupling agent. Examples of the coupling agent include known coupling agents such as silane-based compounds such as epoxysilane, mercaptosilane, aminosilane, alkylsilane, ureidosilane, vinylsilane, and disilazane, titanium-based compounds, aluminum chelate-based compounds, aluminum/zirconium-based compounds, etc.

In the case where the molding resin composition includes a coupling agent, the amount of the coupling agent is preferably 0.05 parts by mass to 5 parts by mass, and more preferably 0.1 parts by mass to 2.5 parts by mass, based on 100 parts by mass of the inorganic filler. When the amount of the coupling agent is 0.05 parts by mass or more based on 100 parts by mass of the inorganic filler, the adhesion to the frame tends to be further improved. When the amount of the coupling agent is 5 parts by mass or less based on 100 parts by mass of the inorganic filler, the moldability of the package tends to be further improved.

### (Ion Exchanger)

The molding resin composition of the present disclosure may include an ion exchanger. The molding resin composition preferably includes an ion exchanger from the viewpoint of improving the moisture resistance and high-temperature storage characteristics of an electronic component device including an electronic component sealed therein. The ion exchanger is not particularly limited, and any conventionally known ion exchanger can be used. Specific examples include hydrotalcite compounds and hydrous oxides of at least one element selected from the group consisting of magnesium, aluminum, titanium, zirconium, and bismuth. The ion exchanger may be used alone or in combination of two or more. Among these, hydrotalcite represented by the following general formula (A) is preferable.

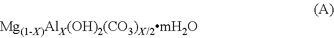

(0<X≤0.5, m is a positive number)

In the case where the molding resin composition includes an ion exchanger, the content thereof is not particularly limited as long as the amount is sufficient to capture ions such as halogen ions. For example, the content of the ion exchanger is preferably 0.1 parts by mass to 30 parts by mass, and more preferably 1 part by mass to 10 parts by mass, based on 100 parts by mass of the curable resin (or 100 parts by mass of the epoxy resin and the curing agent in total).

### (Release Agent)

The molding resin composition of the present disclosure may include a release agent from the viewpoint of obtaining good releasability from a mold during molding. The release agent is not particularly limited, and any conventionally known release agent can be used. Specific examples include carnauba wax, higher fatty acids such as montanic acid and stearic acid, higher fatty acid metal salts, ester-based waxes such as montanic acid ester, polyolefin-based waxes such as oxidized polyethylene and non-oxidized polyethylene, etc. The release agent may be used alone or in combination of two or more.

In the case where the molding resin composition includes a release agent, the amount thereof is preferably 0.01 parts by mass to 10 parts by mass, and more preferably 0.1 parts by mass to 5 parts by mass, based on 100 parts by mass of the curable resin (or 100 parts by mass of the epoxy resin and the curing agent in total). When the amount of the release agent is 0.01 parts by mass or more based on 100 parts by mass of the curable resin (or 100 parts by mass of the epoxy resin and the curing agent in total), sufficient releasability tends to be obtained. When the amount is 10 parts by mass or less, better adhesion tends to be obtained.

### (Flame Retardant)

The molding resin composition of the present disclosure may include a flame retardant. The flame retardant is not particularly limited, and any conventionally known flame retardant can be used. Specific examples include organic or inorganic compounds containing a halogen atom, an antimony atom, a nitrogen atom or a phosphorus atom, metal hydroxides, etc. The flame retardant may be used alone or in combination of two or more.

In the case where the molding resin composition includes a flame retardant, the amount thereof is not particularly limited so long as the amount is sufficient to achieve the desired flame retardant effect. For example, the amount of the flame retardant is preferably 1 part by mass to 30 parts by mass, and more preferably 2 parts by mass to 20 parts by mass, based on 100 parts by mass of the curable resin (or 100 parts by mass of the epoxy resin and the curing agent in total).

### (Colorant)

The molding resin composition of the present disclosure may include a colorant. Examples of the colorant include known colorants such as carbon black, organic dye, organic pigment, titanium oxide, red lead, red iron oxide, etc. The content of the colorant can be appropriately selected depending on the purpose or the like. The colorant may be used alone or in combination of two or more.

### (Method for Preparing Molding Resin Composition)

The method for preparing the molding resin composition is not particularly limited. A typical method involves, for example, thoroughly mixing the components in predetermined amounts using a mixer or the like, melt-kneading the mixture using a mixing roll, an extruder, or the like, cooling, and pulverizing the mixture. More specifically, for example, the above-mentioned components are mixed in predetermined amounts by stirring, kneaded in a kneader, a roll, an extruder, or the like that has been preheated to 70° C. to 140° C., cooled, and pulverized.

The molding resin composition of the present disclosure is preferably a solid at room temperature and normal pressure (for example, 25° C. and atmospheric pressure). In the case where the molding resin composition is a solid, the shape of the molding resin composition is not particularly limited, and examples of the shape include powder, granules, tablets, or the like. In the case where the molding resin composition is in the form of tablets, the dimensions and mass are preferably set to suit the molding conditions of the package from the viewpoint of handleability.

### (Characteristics of Molding Resin Composition)

The molding resin composition of the present disclosure is compression molded under conditions of a mold temperature of 175° C., a molding pressure of 6.9 MPa, and a curing time of 600 seconds, so that the cured product has a relative dielectric constant at 10 GHz of, for example, 8 to 30. The relative dielectric constant of the cured product at 10 GHz is preferably 9 to 30, more preferably 10 to 30, and even more preferably 15 to 25, from the viewpoint of miniaturization of the electronic component such as an antenna.

The measurement of the relative dielectric constant is carried out at a temperature of 25±3° C. using a dielectric constant measuring device (for example, Agilent Technologies, product name “Network Analyzer N5227A”).

The molding resin composition of the present disclosure is compression molded under conditions of a mold temperature of 175° C., a molding pressure of 6.9 MPa, and a curing time of 600 seconds, so that the cured product has a dielectric tangent at 10 GHz of, for example, 0.015 or less. The dielectric tangent at 10 GHz of the cured product is preferably 0.010 or less, more preferably 0.007 or less, and even more preferably 0.0055 or less, from the viewpoint of reducing transmission loss. The lower limit of the dielectric tangent at 10 GHz of the cured product is not particularly limited, and may be, for example, 0.001.

The measurement of the dielectric tangent is carried out at a temperature of 25±3° C. using a dielectric constant measuring device (for example, Agilent Technologies, product name “Network Analyzer N5227A”).

### (Use of Molding Resin Composition)

The molding resin composition of the present disclosure can be used, for example, in the manufacture of an electronic component device, described below, particularly a high-frequency device. The molding resin composition of the present disclosure may be used for sealing an electronic component in a high-frequency device.

In particular, with the spread of fifth-generation mobile communication systems (5G), semiconductor packages (PKGs) used in electronic component devices have become more functional and smaller in recent years. As PKGs become smaller and more functional, development of antenna-in-package (AiP, Antenna in Package), which is a PKG having an antenna function, is also underway. In AiP, the radio waves used for communication are becoming higher in frequency in order to cope with an increase in the number of channels that accompanies the diversification of information, and the sealing material is required to have a low dielectric tangent.

As described above, the molding resin composition of the present disclosure forms a cured product with a low dielectric tangent. Therefore, in a high-frequency device, the molding resin composition is particularly suitable for use as an antenna-in-package (AiP) in which an antenna disposed on a support member is sealed with the molding resin composition.

In an electronic component device including an antenna, such as an antenna-in-package, if an amplifier for supplying power is provided on the opposite side to the antenna, heat is generated due to the power supply. From the viewpoint of improving heat dissipation, the molding resin composition used in the manufacture of the electronic component device preferably includes alumina particles as an inorganic filler.

### <Electronic Component Device>

The electronic component device of the present disclosure includes a support member, an electronic component disposed on the support member, and a cured product of the above-mentioned molding resin composition which seals the electronic component.

Examples of the electronic component device include devices (for example, high-frequency devices) obtained by mounting an electronic component (active elements such as semiconductor chips, transistors, diodes, and thyristors, passive elements such as capacitors, resistors, and coils, antennas, etc.) on a support member such as a lead frame, a pre-wired tape carrier, a wiring board, glass, a silicon wafer, or an organic substrate, and sealing the resulting electronic component region with the molding resin composition.

The type of the support member is not particularly limited, and a support member that is generally used in the manufacture of an electronic component device can be used.

The electronic component may include an antenna, or may include an antenna and an element other than the antenna. The antenna is not limited as long as the antenna can function as an antenna, and may be an antenna element or a wiring.

Furthermore, in the electronic component device of the present disclosure, if necessary, another electronic component may be disposed on the surface of the support member opposite to the surface on which the electronic component is disposed. The another electronic component may be sealed with the above-mentioned molding resin composition, may be sealed with another resin composition, or may not be sealed.

### (Method for Manufacturing Electronic Component Device)

The manufacturing method of the electronic component device of the present disclosure includes a step of disposing an electronic component on a support member, and a step of sealing the electronic component with the above-mentioned molding resin composition.

The method for carrying out each of the above steps is not particularly limited, and each step can be carried out by a general method. Furthermore, there are no particular limitations on the types of the support member and the electronic component used in the manufacture of the electronic component device, and a support member and an electronic component that are generally used in the manufacture of the electronic component device can be used.

Examples of the method for sealing the electronic component using the above-mentioned molding resin composition include low-pressure transfer molding, injection molding, compression molding, etc. Among these, low-pressure transfer molding is typical.

### EXAMPLES

The above embodiment will be specifically described below using examples, but the scope of the above embodiment is not limited to these examples.

### <Preparation of Molding Resin Composition>

The components shown below were mixed in the blending ratios (parts by mass) shown in Table 1 to prepare the molding resin compositions of Examples and Comparative Examples. The molding resin composition was a solid at room temperature and normal pressure.

In Table 1, the blank space indicates that the component is not included.

Table 1 also shows the content of the inorganic filler relative to the entire molding resin composition (“content (% by volume)” in the table).

In addition, the CTO ratio in the table means the content (% by mass or % by volume) of calcium titanate particles relative to the entire inorganic filler, and the alumina ratio in the table means the content (% by mass or % by volume) of alumina particles relative to the entire inorganic filler.
Epoxy resin 1: biphenyl aralkyl type epoxy resin, epoxy equivalent 275 g/eq
Epoxy resin 2: biphenyl type epoxy resin, epoxy equivalent 196 g/eq
Epoxy resin 3: o-cresol novolac type epoxy resin, epoxy equivalent 202 g/eq
Curing agent 1: active ester compound, DIC Corporation, product name “EXB-8”
Curing agent 2: phenol curing agent, biphenyl aralkyl type phenol resin, hydroxyl equivalent 199 g/eq
Curing agent 3: melamine-modified phenol resin, reactive group equivalent 120 g/eq
Curing accelerator: adduct of trialkylphosphine and 1,4-benzoquinone
Coupling agent: N-phenyl-3-aminopropyltrimethoxysilane (Shin-Etsu Chemical Co., Ltd., product name “KBM-573”)
Release agent: montan acid ester wax (Clariant Japan Co., Ltd., product name “Licowax E”)
Colorant: carbon black
Stress relaxer 1: indene-styrene-coumarone copolymer
Stress relaxer 2: triarylphosphine oxide
Inorganic filler 1: calcium titanate particles, volume average particle size: 0.24 μm, shape: irregular
Inorganic filler 2: alumina particles, volume average particle size: 5.7 μm, shape: spherical
Inorganic filler 3: calcium titanate particles, volume average particle size: 23.0 μm, shape: irregular
Inorganic filler 4: alumina particles, volume average particle size: 0.25 μm, shape: spherical

The volume average particle size of each of the inorganic fillers is a value obtained by the following measurement.

Specifically, first, the inorganic filler was added to a dispersion medium (water) in a range of 0.01% by mass to 0.1% by mass, and the mixture was dispersed in a bath type ultrasonic cleaner for 5 minutes.

5 ml of the obtained dispersion liquid was poured into a cell, and the particle size distribution was measured at 25° C. using a laser diffraction/scattering type particle size distribution measuring device (LA920, manufactured by Horiba, Ltd.).

The particle size at an integrated value of 50% (volume basis) in the obtained particle size distribution was defined as the volume average particle size.

### (Evaluation of Spiral Flow (SF))

With use of a spiral flow measurement mold conforming to EMMI-1-66, the thermosetting resin composition was molded with a transfer molding machine under conditions of a mold temperature of 180° C., a molding pressure of 6.9 MPa, and a curing time of 120 seconds, to determine the flow distance (cm). The results are shown in Table 1.

### (Measurement of Relative Dielectric Constant and Dielectric Tangent)

The molding resin composition was charged into a transfer molding machine and molded under conditions of a mold temperature of 180° C., a molding pressure of 6.9 MPa, and a curing time of 90 seconds. Post-curing was carried out at 175° C. for 6 hours to prepare a rectangular parallelepiped test piece of 90 mm×0.6 mm×1.0 mm.

The relative dielectric constant (Dk) and dielectric tangent (Df) of this test piece were measured at a frequency of 10 GHz in an environment at a temperature of 25±3° C. by a cavity resonance method using a cavity resonator (Kanto Electronics Application Development Inc.) and a network analyzer (Keysight Technologies, product name “PNA N5227A”). The results are shown in Table 1.

TABLE 1

| | | Example | Comparative | Comparative | Example | Example | Example | Comparative | Comparative |
|---|---|---|---|---|---|---|---|---|---|
| | | 1 | Example 1 | Example 2 | 2 | 3 | 4 | Example 3 | Example 4 |
| Epoxy resin | Epoxy | 70.1 | 70.1 | | | | | | |
| | resin 1 | | | | | | | | |
| | Epoxy | 29.9 | 29.9 | 29.9 | 29.9 | 29.9 | 29.9 | 29.9 | 29.9 |
| | resin 2 | | | | | | | | |
| | Epoxy | | | 70.1 | 70.1 | 70.1 | 70.1 | 70.1 | 70.1 |
| | resin 3 | | | | | | | | |
| Curing | Curing | 43.9 | 51.6 | 106 | 106 | 106 | 106 | 106 | 106 |
| agent | agent 1 | | | | | | | | |
| | Curing | 20.9 | 24.6 | | | | | | |
| | agent 2 | | | | | | | | |
| | Curing | 4.2 | 4.9 | | | | | | |
| | agent 3 | | | | | | | | |
| Curing | Curing | 3.3 | 3.3 | 5 | 5 | 5 | 5 | 5 | 5 |
| accelerator | accelerator | | | | | | | | |
| Coupling | Coupling | 5 | 5 | 5 | 5 | 5 | 5 | 5 | 5 |
| agent | agent | | | | | | | | |
| Release | Release | 1 | 1 | 1 | 1 | 1 | 1 | 1 | 1 |
| agent | agent | | | | | | | | |
| Colorant | Colorant | 5.3 | 5.3 | 5.3 | 5.3 | 5.3 | 5.3 | 5.3 | 5.3 |
| Stress | Stress | 10 | | 10 | 10 | 10 | 10 | 10 | 10 |
| relaxer | relaxer 1 | | | | | | | | |
| | Stress | 5 | | 5 | 5 | 5 | 5 | 5 | 5 |
| | relaxer 2 | | | | | | | | |
| Content of entire | | 68 | 68 | 68 | 68 | 68 | 68 | 70 | 73 |
| inorganic filler (% by | | | | | | | | | |
| volume) | | | | | | | | | |
| Inorganic | Inorganic | 147 | 145 | | 175 | 175 | 175 | | |
| filler | filler 1 | | | | | | | | |
| | Inorganic | 545 | 537 | 1459 | 405 | 811 | 1216 | 1602 | 1857 |
| | filler 2 | | | | | | | | |
| | Inorganic | 736 | 726 | | 1139 | 701 | 263 | | |
| | filler 3 | | | | | | | | |
| | Inorganic | | | 159 | | | | 174 | 202 |
| | filler 4 | | | | | | | | |
| Total | | 1626.6 | 1603.7 | 1896.7 | 1956.3 | 1924.3 | 1891.3 | 2058.7 | 2346.7 |
| SF | cm | 93 | 80 | 253 | 78 | 130 | 188 | 203 | 140 |
| CTO ratio | % by mass | 61.8 | 61.9 | 0.0 | 76.4 | 51.9 | 26.5 | 0.0 | 0.0 |
| Alumina | % by mass | 38.2 | 38.1 | 100.0 | 23.6 | 48.1 | 73.5 | 100.0 | 100.0 |
| ratio | | | | | | | | | |
| CTO ratio | % by | 60 | 60 | 0 | 75 | 50 | 25 | 0 | 0 |
| | volume | | | | | | | | |
| Alumina | % by | 40 | 40 | 100 | 25 | 50 | 75 | 100 | 100 |
| ratio | volume | | | | | | | | |
| Dk@10 GHz | — | 22.6 | 23.1 | 5.9 | 26.2 | 15.9 | 9.7 | 7.1 | 7.6 |
| Df@10 GHz | — | 0.0052 | 0.0060 | 0.0032 | 0.0045 | 0.0041 | 0.0036 | 0.0031 | 0.0029 |

As shown in Table 1, the molding resin compositions of the Examples were capable of molding cured products having low dielectric tangents while maintaining the relative dielectric constants. On the other hand, the cured product obtained in Comparative Example 1 had a higher dielectric tangent than the cured product obtained in each of the Examples. The cured products obtained in Comparative Examples 2 to 4 had a lower relative dielectric constant than the cured product obtained in each of the Examples.

The entirety of the disclosure of Japanese Patent Application No. 2022-094676 is incorporated into this specification by reference.

All the documents, patent applications, and standards mentioned in this specification are incorporated by reference into this specification to the same extent as if each individual document, patent application, and standard is specifically and individually incorporated by reference.

1. A molding resin composition, comprising:
a curable resin;
an inorganic filler comprising at least one of silica particles and alumina particles, and calcium titanate particles; and
a stress relaxer,
wherein the stress relaxer comprises at least one of an indene-styrene-coumarone copolymer, a trialkylphosphine oxide, and a triarylphosphine oxide.

2. The molding resin composition according to claim 1, wherein a content of the calcium titanate particles is 30% by volume to 90% by volume based on the entire inorganic filler.

3. The molding resin composition according to claim 1, wherein the curable resin comprises an epoxy resin, and the molding resin composition further comprises a curing agent.

4. The molding resin composition according to claim 3, wherein the curing agent comprises an active ester compound.

5. The molding resin composition according to claim 3, wherein the curing agent comprises a phenol curing agent.

6. The molding resin composition according to claim 5, wherein the phenol curing agent comprises a melamine-modified phenol resin.

7. The molding resin composition according to claim 1, wherein a total content of the inorganic filler is more than 55% by volume based on the entire molding resin composition.

8. The molding resin composition according to claim 1, which is used for a high-frequency device.

9. The molding resin composition according to claim 8, which is used for sealing an electronic component in a high-frequency device.

10. The molding resin composition according to claim 1, which is used for an antenna-in-package.

11. An electronic component device, comprising:
a support member;
an electronic component disposed on the support member; and
a cured product of the molding resin composition according to claim 1 which seals the electronic component.

12. The electronic component device according to claim 11, wherein the electronic component comprises an antenna.

13. The molding resin composition according to claim 1, wherein the stress relaxer comprises an indene-styrene-coumarone copolymer and a triarylphosphine oxide.

14. The molding resin composition according to claim 13, wherein a mass ratio of the indene-styrene-coumarone copolymer to the triarylphosphine oxide, which is indene-styrene-coumarone copolymer: triarylphosphine oxide, is 1:1 to 5:1.
